(19) United States
(12) Patent Application Publication
(10) Pub. No.: US 2026/0314231 A1
(43) Pub. Date: Oct. 8, 2026

(54) DISPLAY SUBSTRATE AND FABRICATION METHOD THEREFOR, AND DISPLAY APPARATUS

(71) Applicants: Chongqing BOE Display Technology Co.,Ltd., Chongqing (CN); BOE Technology Group Co., Ltd., Beijing (CN)

(72) Inventors: Weidi XIA, Beijing (CN); Yuanyou QIU, Beijing (CN); Shouqiang ZHANG, Beijing (CN)

(21) Appl. No.: 19/481,177

(22) PCT Filed: Jan. 3, 2025
(86) PCT No.: PCT/CN2025/070422

§ 371 Date: Nov. 4, 2025

(30) Foreign Application Priority Data
Jan. 5, 2024 (CN) 202410021683.2

(51) Int. Cl. H10K 59/80; H10K 59/12; H10K 59/122

(52) U.S. Cl. CPC H10K 59/80522; H10K 59/1201; H10K 59/122

(57) ABSTRACT

A display substrate and a fabrication method therefor, and a display apparatus. The display substrate comprises partition structures (10) disposed on a substrate; an anode disposed on the substrate, wherein the orthographic projections of the anode and the partition structures (10) do not overlap on the substrate; a light-emitting layer (7) disposed on the side of the anode away from the substrate, the light-emitting layer (7) being connected to the anode and being interrupted at the partition structures (10); a cathode (3) disposed on the side of the light-emitting layer (7) away from the substrate, the cathode (3) being connected to the light-emitting layer (7) and being interrupted at the partition structures (10); and an auxiliary cathode (20) located on the same film layer as the anode and insulated from the anode, the auxiliary cathode (20) being electrically connected to the cathode (3).

### CROSS-REFERENCE TO RELATED APPLICATIONS

The present application is a U.S. National Phase Entry of International Application No. PCT/CN2025/070422 having an international filing date of Jan. 3, 2025, which claims priority to Chinese Patent Application No. 202410021683.2, filed to the CNIPA on Jan. 5, 2024 and entitled “Display Substrate and Fabrication Method Therefor, and Display Apparatus”. Contents of the above-identified applications are incorporated into the present application by reference.

### TECHNICAL FIELD

The present disclosure relates to, but is not limited to, the field of display technologies, and particularly to a display substrate and a fabrication method therefor, and a display apparatus.

### BACKGROUND

An organic light-emitting diode (OLED) and a quantum dot light-emitting diode (QLED) are active light-emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light-emitting device and signal control is performed through a thin film transistor (TFT) has become a mainstream product in the field of display at present.

### SUMMARY

The present application provides a display substrate, including: a partition structure disposed on a base substrate; an anode disposed on the base substrate, an orthographic projection of the anode on the base substrate not overlapping with an orthographic projection of the partition structure on the base substrate; a light-emitting layer disposed on a side of the anode away from the base substrate, the light-emitting layer being connected to the anode and blocked at the partition structure; a cathode disposed on a side of the light-emitting layer away from the base substrate, the cathode being connected to the light-emitting layer and blocked at the partition structure; and an auxiliary cathode located in the same film layer as the anode. The auxiliary cathode and the anode are insulated from each other, and the auxiliary cathode is electrically connected to the cathode.

In an exemplary implementation, the display substrate further includes a connection via disposed between the auxiliary cathode and the cathode. The cathode is connected to the auxiliary cathode through the connection via, and an orthographic projection of the connection via on the base substrate does not overlap with either the orthographic projection of the anode on the base substrate or the orthographic projection of the partition structure on the base substrate.

In an exemplary implementation, a connection avoidance hole is provided in the light-emitting layer, and an orthographic projection of the connection avoidance hole on the base substrate covers the orthographic projection of the connection via on the base substrate.

In an exemplary implementation, the auxiliary cathode and the anode include a same conductive material.

In an exemplary implementation, a shape of the auxiliary cathode is grid-like.

In an exemplary implementation, a bump is provided on the auxiliary cathode, the bump protrudes from an edge of the auxiliary cathode, and the bump is electrically connected to the cathode.

In an exemplary implementation, an orthographic projection of the auxiliary cathode on the base substrate is within an orthographic projection of the cathode on the base substrate.

In an exemplary implementation, the partition structure includes a first separation wall disposed on the base substrate, and the first separation wall includes a first separation layer and a second separation layer disposed on a side of the first separation layer away from the base substrate. At least a portion of the second separation layer protrudes from a sidewall of the first separation layer along a direction parallel to the base substrate to form a boss at which the light-emitting layer and the cathode are blocked.

In an exemplary implementation, the partition structure further includes a second separation wall, a separation groove is formed between the second separation wall and the first separation wall, and the second separation wall includes a third separation layer and a fourth separation layer disposed on a side of the third separation layer away from the base substrate. At least a portion of a stacked structure formed by the light-emitting layer and the cathode covers a sidewall of the third separation layer and a sidewall of the fourth separation layer, and at least a portion of the stacked structure formed by the light-emitting layer and the cathode covers a groove bottom of the separation groove.

In an exemplary implementation, the display substrate further includes an organic dielectric layer and an inorganic dielectric layer, and the organic dielectric layer is disposed on the base substrate. The inorganic dielectric layer is disposed on a side of the organic dielectric layer away from the base substrate, and the anode is disposed on a side of the inorganic dielectric layer away from the base substrate. The first separation layer is integrally connected with the organic dielectric layer adjacent thereto, the third separation layer is integrally connected with the organic dielectric layer adjacent thereto, the second separation layer is integrally connected with the inorganic dielectric layer adjacent thereto, and the fourth separation layer is integrally connected with the inorganic dielectric layer adjacent thereto. The groove bottom of the separation groove is the organic dielectric layer.

In an exemplary implementation, the display substrate includes a first sub-pixel region, a second sub-pixel region and a third sub-pixel region. The first sub-pixel region includes a first anode, a light-emitting layer, and a cathode, the second sub-pixel region includes a second anode, a light-emitting layer, and a cathode, and the third sub-pixel region includes a third anode, a light-emitting layer, and a cathode. The first sub-pixel region and the second sub-pixel region are arranged along a second direction to form a sub-pixel column, the third sub-pixel region is located on a side of the sub-pixel column in a first direction, the partition structure is provided on at least one side of the first sub-pixel region, the second sub-pixel region, the third sub-pixel region, and the first direction intersects with the second direction.

In an exemplary implementation, the auxiliary cathode is disposed around a periphery of the first sub-pixel region, around a periphery of the second sub-pixel region, and around a periphery of the third sub-pixel region.

In an exemplary implementation, the display substrate further includes a connection via disposed between the auxiliary cathode and the cathode, and the cathode is connected to the auxiliary cathode through the connection via. An orthographic projection of the connection via on the base substrate does not overlap with either the orthographic projection of the anode on the base substrate or the orthographic projection of the partition structure on the base substrate, and the connection via is located on at least one side of the third sub-pixel region in the second direction.

In an exemplary implementation, the display substrate includes a first partition structure, a second partition structure, a third partition structure, a fourth partition structure, a fifth partition structure, and a sixth partition structure. A shape of the first partition structure includes a linear shape extending along the first direction, and the first partition structure is disposed between the first sub-pixel region and the second sub-pixel region. A shape of the second partition structure includes a linear shape extending along the second direction, and the second partition structure is disposed on a side of the first sub-pixel region away from the third sub-pixel region. A shape of the third partition structure includes a linear shape extending along the first direction, and the third partition structure is disposed on a side of the second sub-pixel region away from the first sub-pixel region. A shape of the fourth partition structure includes a linear shape extending along the second direction, and the fourth partition structure is disposed on a side of the second sub-pixel region away from the third sub-pixel region. A shape of the fifth partition structure includes a linear shape extending along the second direction, and the fifth partition structure is disposed between the third sub-pixel region and the first sub-pixel region. A shape of the sixth partition structure includes a linear shape extending along the second direction, and the sixth partition structure is disposed between the third sub-pixel region and the second sub-pixel region.

In an exemplary implementation, the display substrate further includes a pixel definition layer disposed on a side of the anode away from the base substrate. The pixel definition layer is provided with a pixel opening that exposes at least a portion of the anode, the light-emitting layer covers the pixel opening and is connected with the anode, and the pixel definition layer is further provided with a connection via through which the cathode is connected with the auxiliary cathode. An orthographic projection of the connection via on the base substrate does not overlap with either the orthographic projection of the anode on the base substrate or the orthographic projection of the partition structure on the base substrate.

In an exemplary implementation, the pixel definition layer is further provided with a partition avoidance hole, and an orthographic projection of the partition avoidance hole on the base substrate overlaps with the orthographic projection of the partition structure on the base substrate.

The present application further provides a display apparatus which includes the display substrate describe above.

The present application further provides a method for preparing a display substrate, including: forming a partition structure on a base substrate; forming a conductive thin film on the base substrate, such that the conductive thin film forms an anode and an auxiliary cathode that are insulated from each other, an orthographic projection of the anode on the base substrate does not overlap with an orthographic projection of the partition structure on the base substrate, and an orthographic projection of the auxiliary cathode on the base substrate does not overlap with the orthographic projection of the partition structure on the base substrate; forming a light-emitting layer on a side of the anode away from the base substrate, the light-emitting layer being connected to the anode, and the light-emitting layer being blocked at the partition structure; and forming a cathode on a side of the light-emitting layer away from the base substrate, the cathode being connected to the light-emitting layer, and the cathode being blocked at the partition structure, and the cathode being electrically connected to the auxiliary cathode.

Other features and advantages of the present application will be set forth in the specification which follows, and in part will become apparent from the specification, or may be learned by practice of the present application. Other advantages of the present application may be achieved and obtained through solutions described in the specification and drawings.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a structure of a display apparatus;

FIG. 2 is a schematic diagram of a planar structure of a display area in a display apparatus;

FIG. 3 is a schematic diagram of a cross-sectional structure of a display area in a display apparatus;

FIG. 4a is a schematic diagram of a planar structure of a display substrate according to an embodiment of the present disclosure;

FIG. 4b is a schematic diagram of a cross-sectional structure of a display substrate according to an embodiment of the present disclosure;

FIG. 5 is a schematic diagram of a cross-sectional structure of a display substrate according to an embodiment of the present disclosure;

FIG. 6 is a schematic diagram of a display substrate after forming an inorganic dielectric layer and a partition structure according to an embodiment of the present disclosure;

FIGS. 7a and 7b are schematic diagrams of a display substrate after forming a first anode, a second anode, a third anode, and an auxiliary cathode according to an embodiment of the present disclosure;

FIGS. 8a and 8b are schematic diagrams of a display substrate after forming a pixel definition layer according to an embodiment of the present disclosure; and

FIG. 9 is a schematic diagram of a display substrate after forming a cathode according to an embodiment of the present disclosure.

### DETAILED DESCRIPTION

A plurality of embodiments is described in the present application. However, the description is exemplary and unrestrictive. Moreover, it is apparent to those of ordinary skills in the art that there may be more embodiments and implementation solutions within the scope of the embodiments described in the present application. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

The present application includes and conceives combinations of features and elements well known to those of ordinary skills in the art. The embodiments, features and elements that have been disclosed in the present application may be combined with any conventional features or elements to form unique inventive solutions defined by the claims. Any feature or element of any embodiment may also be combined with a feature or an element from another inventive solution to form another unique inventive solution defined by the claims. Therefore, it should be understood that any feature shown and/or discussed in the present application may be implemented independently or in any appropriate combination. Therefore, the embodiments are not limited except the limitations by the appended claims and equivalents thereof. Furthermore, various modifications and variations may be made within the protection scope of the appended claims.

Moreover, when describing representative embodiments, the specification may have presented a method and/or a process as a particular sequence of acts. However, to an extent that the method or the process does not depend on the specific sequence of the acts described herein, the method or the process should not be limited to the acts with the specific sequence. Those of ordinary skills in the art will understand that other sequences of acts are also possible. Therefore, the specific sequence of the acts illustrated in the specification should not be interpreted as a limitation on claims. Moreover, the execution of the acts in the claims for the method and/or the process should not be limited to the written sequence, and it can be easily understood by those skilled in the art that these sequences may be changed and still fall within the spirit and scope of the embodiments of the present application.

Through research, the inventors of the present application have found that a Tandem OLED display substrate is a stacked device formed by connecting a plurality of stacked light-emitting layers together through a connection layer. The connection layer generally includes a p-type semiconductor material and an n-type semiconductor material. The cathode of the Tandem OLED display substrate injects electrons and the anode injects holes. After the electrons and holes are separated at the connection layer, power can be supplied to the light-emitting layer to realize light emission. In different pictures, the light-emitting brightness of the R sub-pixel, the G sub-pixel, and the B sub-pixel is different, resulting in different currents for lighting the R sub-pixel, the G sub-pixel, and the B sub-pixel. Since the Tandem OLED display substrate requires a large cross-voltage drive, when the sub-pixel with a large lighting current is lit, the current will flow to the adjacent sub-pixel, causing the sub-pixel with a small lighting current to be lit, causing the sub-pixel with a low gray scale to be lit, thus affecting the image quality. The high-brightness Tandem OLED display substrate requires a larger cross-voltage, and the larger cross-voltage will lead to the more serious problem of low gray scale sub-pixel lighting. In order to solve the problem of lighting up low gray-scale sub-pixels in the Tandem OLED display substrate, a partition structure can be provided between adjacent sub-pixels in the Tandem OLED display substrate, and the partition structure can partition the cathodes of adjacent sub-pixels to reduce current crosstalk of adjacent sub-pixels. However, the partition structure will increase the surface resistance of the cathode, reduce the power supply voltage drop and brightness uniformity, and reduce the uniformity of the display picture.

The present disclosure provides a display substrate, which includes: a partition structure disposed on a base substrate; an anode disposed on the base substrate, an orthographic projection of the anode on the base substrate not overlapping with an orthographic projection of the partition structure on the base substrate; a light-emitting layer disposed on a side of the anode away from the base substrate, the light-emitting layer being connected to the anode and blocked at the partition structure; a cathode disposed on a side of the light-emitting layer away from the base substrate, the cathode being connected to the light-emitting layer and blocked at the partition structure; and an auxiliary cathode located in the same film layer as the anode and insulated from the anode, the auxiliary cathode being electrically connected to the cathode.

The technical solutions of the embodiments of the present invention will be illustrated in detail below by the specific embodiments.

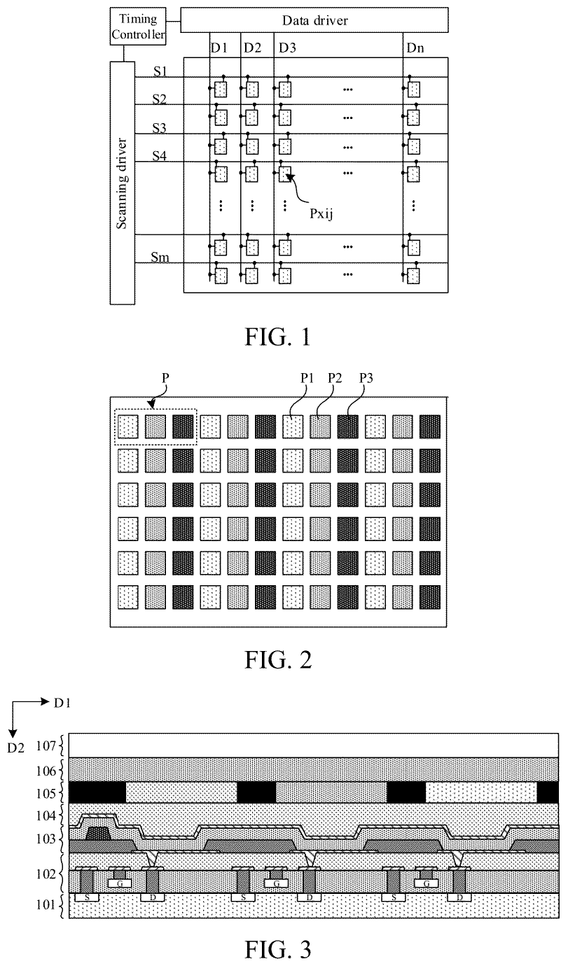

FIG. 1 is a schematic diagram of a structure of a display apparatus. As shown in FIG. 1, the display apparatus may include a timing controller, a data signal driver, a scan signal driver and a pixel array. The pixel array may include multiple scan signal lines (S1 to Sm), multiple data signal lines (D1 to Dn) and multiple sub-pixels Pxij.

In an exemplary implementation, the timing controller may provide the data signal driver with a gray scale value and a control signal which are suitable for a specification of the data signal driver, and provide the scan signal driver with a clock signal, a scan start signal and the like which are suitable for a specification of the scan signal driver. The data signal driver may generate data voltages to be provided to data signal lines D1, D2, D3, . . . , and Dn using the gray scale value and the control signal received from the timing controller. For example, the data signal driver may sample gray scale values using the clock signal and apply the data voltages corresponding to the gray scale values to the data signal lines D1 to Dn by taking a row of sub-pixels as a unit, where n may be a natural number. The scan signal driver may generate scan signals to be provided to scan signal lines S1, S2, S3, . . . , and Sm by receiving a clock signal, a scan start signal, and the like from the timing controller. For example, the scan signal driver may sequentially provide scan signals with turning-on-level pulses to the scan signal lines S1 to Sm. For example, the scan signal driver may be constructed in a form of a shift register, and generate the scan signals in a mode of sequentially transmitting the scan start signal provided in a form of turning-on-level pulses to a next-stage circuit under controlling of the clock signal, where m may be a natural number. A sub-pixel array may include multiple sub-pixels Pxij. Each sub-pixel Pxij may be connected to a corresponding data signal line and a corresponding scan signal line, in which i and j may be natural numbers. The sub-pixel Pxij may refer to a sub-pixel in which a transistor is connected to both an i-th scan signal line and a j-th data signal line.

FIG. 2 is a schematic diagram of a planar structure of a display area in a display apparatus. As shown in FIG. 2, the display area may include multiple pixel units P arranged in a matrix manner. At least one of the multiple pixel units P includes a first sub-pixel P1 emitting light of a first color, a second sub-pixel P2 emitting light of a second color, and a third sub-pixel P3 emitting light of a third color, and the first sub-pixel P1, the second sub-pixel P2, and the third sub-pixel P3 each include a pixel drive circuit and a light-emitting device. The pixel drive circuit in the sub-pixel is respectively connected with a scan signal line and a data signal line, and the pixel drive circuit is configured to receive a data voltage transmitted by the data signal line and output a corresponding current to the light-emitting device for display, under control of the scan signal line. The light-emitting device for display in the sub-pixel is connected to the pixel drive circuit of the sub-pixel where the light-emitting device for display is located, and the light-emitting device for display is configured to emit light with a corresponding brightness in response to the current outputted by the pixel drive circuit of the sub-pixel where the light-emitting device for display is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a shape of the sub-pixel may be any one or more of a triangle, a square, a rectangle, a rhombus, a trapezoid, a parallelogram, a pentagon, a hexagon, and another polygon. The sub-pixel may be arranged side by side horizontally, side by side vertically, in a shape of X, in a shape of a Chinese character “ [symbol] ”, in a shape of a Chinese character “ [symbol] ”, in a shape of a square, in a shape of a diamond, or in a shape of a delta, etc., and the present disclosure is not limited thereto.

In an exemplary implementation, the pixel unit may include four sub-pixels, which is not limited in the present disclosure.

FIG. 3 is a schematic diagram of a cross-sectional structure of a display area in a display apparatus, which illustrates a structure in which a manner of white light+color film is adopted to achieve full color. As shown in FIG. 3, the display apparatus may include a base substrate 101, a drive circuit layer 102 disposed on the base substrate 101, a light-emitting structure layer 103 disposed on a side of the drive circuit layer 102 away from the base substrate 101, a first encapsulation layer 104 disposed on a side of the light-emitting structure layer 103 away from the base substrate 101, a color film structure layer 105 disposed on a side of the first encapsulation layer 104 away from the base substrate 101, a second encapsulation layer 106 disposed on a side of the color film structure layer 105 away from the base substrate 101, and a cover plate layer 107 disposed on a side of the second encapsulation layer 106 away from the base substrate 101. In some possible implementations, the display apparatus may include other film layers, and the present disclosure is not limited thereto.

In an exemplary implementation, the base substrate 101 may be a bulk silicon base substrate or a silicon-on-insulator (SOI) base substrate. The drive circuit layer 102 may be manufactured on the base substrate 101 by a silicon semiconductor process (e.g., a CMOS process), and the drive circuit layer 102 may include multiple circuit units. The circuit units may include at least a pixel drive circuit, the pixel drive circuit is connected to a scan signal line and a data signal line, and the pixel drive circuit may include multiple transistors and a storage capacitor. A transistor may include a control electrode G, a first electrode S, and a second electrode D. The control electrode G, the first electrode S, and the second electrode D may be respectively connected with corresponding connection electrodes through vias filled with wolfram metal (i.e., wolfram vias, W-vias), and may be connected with other electrical structures (such as wires) through the connection electrodes.

In an exemplary implementation, the light-emitting structure layer 103 may include a plurality of light-emitting devices, and a light-emitting device may at least include an anode, an organic light-emitting layer, and a cathode. The anode may be connected to the second electrode D of the transistor through a connection electrode, the organic light-emitting layer is connected to the anode, the cathode is connected to the organic light-emitting layer, and the cathode is connected to a cathode voltage line. The organic light-emitting layer emits light under drive of the anode and the cathode. In an exemplary implementation, the organic light-emitting layer may include an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, for a light-emitting device emitting white light, organic light-emitting layers of all sub-pixels may be connected together to form a common layer.

In an exemplary implementation, the first encapsulation layer 104 and the second encapsulation layer 106 may be encapsulated in a manner of Thin Film Encapsulation (TFE), so as to ensure that external water vapor cannot enter the light-emitting structure layer. The cover plate layer 107 may be made of glass, or plastic colorless polyimide having flexible characteristics, etc.

In an exemplary implementation, the color film structure layer 105 may include a black matrix (BM) and color filters (CF). A position of a color filter may correspond to a position of a light-emitting device, and the black matrix may be located between adjacent color filters. The color filter is configured to filter the white light emitted by the light-emitting device into red (R) light, green (G) light, and blue (B) light, forming red, green, and blue sub pixels.

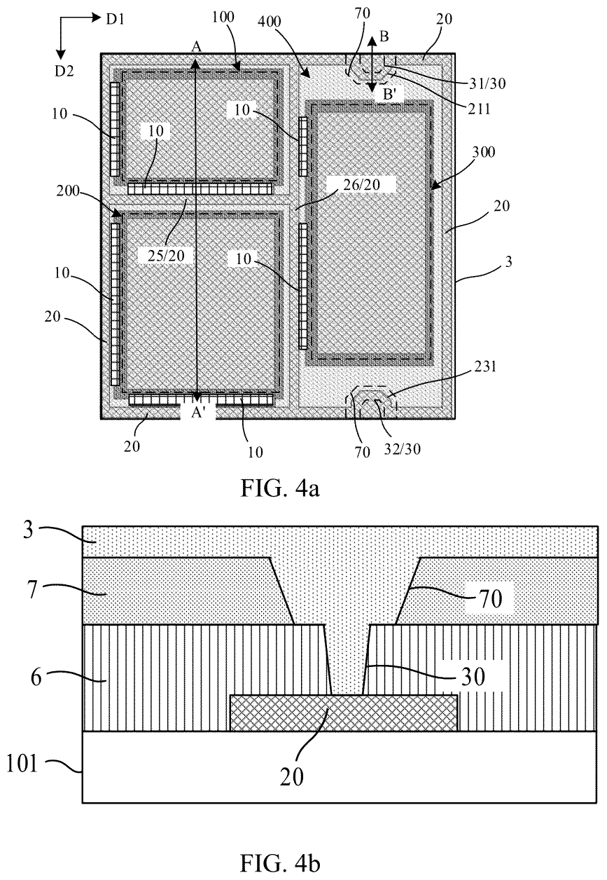

FIG. 4a is a schematic diagram of a planar structure of a display substrate according to an embodiment of the present disclosure, illustrating a structure of one pixel unit. In an exemplary implementation, as shown in FIG. 4a, the display substrate may include a first sub-pixel region 100, a second sub-pixel region 200, a third sub-pixel region 300, and a non-sub-pixel region 400, in a direction parallel to the display substrate. The first sub-pixel region 100 includes a first sub-pixel disposed on a base substrate that emits light of a first color, and the first sub-pixel includes a first anode, a light-emitting layer disposed on a side of the first anode away from the base substrate, and a cathode disposed on a side of the light-emitting layer away from the base substrate. The second sub-pixel region 200 includes a second sub-pixel disposed on a base substrate that emits light of a second color, and the second sub-pixel includes a second anode, a light-emitting layer disposed on a side of the second anode away from the base substrate, and a cathode disposed on a side of the light-emitting layer away from the base substrate. The third sub-pixel region 300 includes a third sub-pixel disposed on a base substrate that emits light of the third color, and the third sub-pixel includes a third anode, a light-emitting layer disposed on a side of the second anode away from the base substrate, and a cathode disposed on a side of the light-emitting layer away from the base substrate. The non-sub-pixel region 400 is a region in which the display substrate does not emit light, and the non-sub-pixel region 400 may be located around the first sub-pixel region 100, around the second sub-pixel region 200, and around the third sub-pixel region 300.

In an exemplary implementation, the first sub-pixel region 100, the second sub-pixel region 200, and the third sub-pixel region 300 may share one cathode 3 and a light-emitting layer, that is, the cathode 3 and the light-emitting layer may be connected together to form a common layer.

In an exemplary implementation, the shapes of the first sub-pixel region 100, the second sub-pixel region 200, and the third sub-pixel region 300 are all rectangular. The first sub-pixel region 100 and the second sub-pixel region 200 may be arranged at intervals along a second direction D2 to form a sub-pixel row. The third sub-pixel region 300 is located on a side of the sub-pixel row in a first direction D1. The first sub-pixel region 100, the second sub-pixel region 200, and the third sub-pixel region 300 are arranged in a shape of a Chinese character “ [symbol] ”. The first direction D1 and the second direction D2 are both parallel to a plane where the display substrate is located, and the first direction D1 intersects with the second direction D2, for example, the first direction D1 is perpendicular to the second direction D2.

In an exemplary implementation, the display substrate may further include a partition structure 10 disposed on the base substrate. The partition structure 10 is located in the non-sub-pixel region 400, and the partition structure 10 is provided on at least one side of the first sub-pixel region 100, the second sub-pixel region 200, and the third sub-pixel region 300. The partition structure 10 is used to partition the light-emitting layer and the cathode 3 of the adjacent sub-pixel region, avoid current crosstalk of the adjacent sub-pixel region, and solve the problem that the sub-pixel of low gray scale is lit.

In an exemplary implementation, the display substrate may include a first partition structure 11, a second partition structure 12, a third partition structure 13, a fourth partition structure 14, a fifth partition structure 15, and a sixth partition structure 16.

In an exemplary implementation, the shape of the first partition structure 11 is a linear shape and extends along the first direction D1, and the first partition structure 11 is located in the non-sub-pixel region 400. The first partition structure 11 is provided on a side of the first sub-pixel region 100 in the second direction D2, and is provided between the first sub-pixel region 100 and the second sub-pixel region 200. The light-emitting layer and the cathode 3 may be blocked at the first partition structure 11 to avoid current crosstalk between the sub-pixels of the first sub-pixel region 100 and the sub-pixels of the second sub-pixel region 200.

In an exemplary implementation, the shape of the second partition structure 12 is a linear shape and extends along the second direction D2, and the second partition structure 12 is located in the non-sub-pixel region 400. The second partition structure 12 is provided on a side of the first sub-pixel region 100 in a direction opposite to the first direction D1, and is provided on a side of the first sub-pixel region 100 away from the third sub-pixel region 300. The light-emitting layer and the cathode 3 may be blocked at the second partition structure 12 to avoid current crosstalk between the sub-pixels of the first sub-pixel region 100 and the sub-pixels of the adjacent pixel units.

In an exemplary implementation, the shape of the third partition structure 13 is a linear shape and extends along the first direction D1, and the third partition structure 13 is located in the non-sub-pixel region 400. The third partition structure 13 is provided on a side of the second sub-pixel region 200 in the second direction D2, and is provided on a side of the second sub-pixel region 200 away from the first sub-pixel region 100. The light-emitting layer and the cathode 3 may be blocked at the third partition structure 13 to avoid current crosstalk between the sub-pixels of the second sub-pixel region 200 and the sub-pixels of the adjacent pixel units.

In an exemplary implementation, the shape of the fourth partition structure 14 is a linear shape and extends along the second direction D2, and the fourth partition structure 14 is located in the non-sub-pixel region 400. The fourth partition structure 14 is provided on a side of the second sub-pixel region 200 in a direction opposite to the first direction D1, and is provided on a side of the second sub-pixel region 200 away from the third sub-pixel region 300. The light-emitting layer and the cathode 3 may be blocked at the fourth partition structure 14 to avoid current crosstalk between the sub-pixels of the second sub-pixel region 200 and the sub-pixels of the adjacent pixel units.

In an exemplary implementation, the shape of the fifth partition structure 15 is a linear shape and extends along the second direction D2, and the fifth partition structure 15 is located in the non-sub-pixel region 400. The fifth partition structure 15 is provided on a side of the third sub-pixel region 300 in a direction opposite to the first direction D1, and is provided between the third sub-pixel region 300 and the first sub-pixel region 100. The light-emitting layer and the cathode 3 may be blocked at the fifth partition structure 15 to avoid current crosstalk between the sub-pixels of the third sub-pixel region 300 and the sub-pixels of the first sub-pixel region 100.

In an exemplary implementation, the shape of the sixth partition structure 16 is a linear shape and extends along the second direction D2, and the sixth partition structure 16 is located in the non-sub-pixel region 400. The sixth partition structure 16 is provided on a side of the third sub-pixel region 300 in a direction opposite to the first direction D1, and is provided between the third sub-pixel region 300 and the second sub-pixel region 200. The light-emitting layer and the cathode 3 may be blocked at the sixth partition structure 16 to avoid current crosstalk between the sub-pixels of the third sub-pixel region 300 and the sub-pixels of the second sub-pixel region 200.

In an exemplary implementation, the display substrate may further include an auxiliary cathode 20 disposed on the base substrate. The auxiliary cathode 20 is located in the non-sub-pixel region 400, and an orthographic projection of the auxiliary cathode 20 on the base substrate does not overlap with orthographic projections of the first sub-pixel region 100, the second sub-pixel region 200, and the third sub-pixel region 300 on the base substrate. The auxiliary cathode 20 may be located in the same film layer as the anode of the sub-pixel, the orthographic projection of the auxiliary cathode 20 on the base substrate may not overlap with an orthographic projection of the anode on the base substrate, and the auxiliary cathode 20 and the anode may be insulated from each other. The orthographic projection of the auxiliary cathode 20 on the base substrate may overlap with the orthographic projection of the cathode 3 on the base substrate. For example, the orthographic projection of the auxiliary cathode 20 on the base substrate is within the orthographic projection of the cathode 3 on the base substrate. The auxiliary cathode 20 may be electrically connected to the cathode 3.

In the display substrate of the embodiment of the present disclosure, the auxiliary cathode 20 is electrically connected to the cathode 3, thereby reducing the resistance of the cathode 3, increasing the power supply voltage drop, and improving the uniformity of brightness and the uniformity of the display picture.

In an exemplary implementation, the auxiliary cathode 20 may be prepared using the same conductive material as the anode of the light-emitting device by the same preparation process, thereby simplifying the preparation process and reducing the production cost.

In an exemplary implementation, the orthographic projection of the auxiliary cathode 20 on the base substrate and the orthographic projection of the partition structure 10 on the base substrate do not overlap. In this way, the auxiliary cathode 20 is prevented from being blocked at the partition structure 10, and the reduction of the resistance of the auxiliary cathode 20 to the cathode 3 is reduced, resulting in a larger resistance of the cathode 3.

In an exemplary implementation, the shape of the auxiliary cathode 20 is grid-like. The auxiliary cathode 20 may be disposed around a periphery of the first sub-pixel region 100, around a periphery of the second sub-pixel region 200, and around a periphery of the third sub-pixel region 300.

In an exemplary implementation, the display substrate may further include a connection via 30 provided between the auxiliary cathode 20 and the cathode 3, and an orthographic projection of the connection via 30 on the base substrate does not overlap with either the orthographic projection of the anode on the base substrate or the orthographic projection of the partition structure 10 on the base substrate. The connection via 30 may be located in the non-sub-pixel region 400, the connection via 30 exposing at least a portion of the auxiliary cathode 20, and at least a portion of the cathode 3 is connected to the auxiliary cathode 20 through the connection via 30.

In an exemplary implementation, the orthographic projection of the connection via 30 on the base substrate overlaps with the orthographic projections of both the cathode 3 and the auxiliary cathode 20 on the base substrate. For example, the orthographic projection of the connection via 30 on the base substrate is within the orthographic projections of the cathode 3 and the auxiliary cathode 20 on the base substrate.

In an exemplary implementation, the shape of the orthographic projection of the connection via 30 on the base substrate may include at least one of a circle, an ellipse, a diamond, a rectangle, a pentagon, a hexagon, a heptagon, and an octagon.

In an exemplary implementation, the display substrate may further include a first connection via 31 and a second connection via 32, both of which are disposed on a side of the auxiliary cathode 20 away from the base substrate, and expose the auxiliary cathode 20. The first connection via 31 is provided on a side of the third sub-pixel region 300 in a direction opposite to the second direction D2. The auxiliary cathode 20 is provided with a first bump 211 that protrudes from an edge of the auxiliary cathode 20 in the second direction D2, and the first bump 211 protrudes in a direction toward the third sub-pixel region 300. An orthographic projection of the first connection via 31 on the base substrate overlaps with an orthographic projection of the first bump 211 on the base substrate. The first connection via 31 exposes at least a portion of the first bump 211, and at least a portion of the cathode 3 is connected to the first bump 211 through the first connection via 31. The second connection via 32 is provided on a side of the third sub-pixel region 300 in the second direction D2. The auxiliary cathode 20 is provided with a second bump 231 protruding from the edge of the auxiliary cathode 20 in the second direction D2, and the second bump 231 protrudes in a direction toward the third sub-pixel region 300. An orthographic projection of the second connection via 32 on the base substrate overlaps with an orthographic projection of the second bump 231 on the base substrate. The second connection via 32 exposes at least a portion of the second bump 231, and at least a portion of the cathode 3 is connected to the second bump 231 through the second connection via 32.

In an exemplary implementation, a connection avoidance hole 70 is provided in the light-emitting layer, and an orthographic projection of the connection avoidance hole 70 on the base substrate covers the orthographic projection of the connection via 30 on the base substrate, When the cathode 3 is connected to the auxiliary cathode 20 through the connection via 30, the light-emitting layer located between the cathode 3 and the auxiliary cathode 20 is separated from the cathode 3 by the connection avoidance hole 70. The light-emitting layer is insulated from the cathode 3 in the connection via 30 by the insulating material in the connection avoidance hole 70.

FIG. 4b is a schematic diagram of a cross-sectional structure of a display substrate according to an embodiment of the present disclosure, illustrating a cross-sectional view of FIG. 4a in a direction B-B′. In an exemplary implementation, as shown in FIG. 4b, in a direction perpendicular to the display substrate, the display substrate may include a base substrate 101, an auxiliary cathode 20 disposed on the base substrate 101, a pixel definition layer 6 disposed on a side of the auxiliary cathode 20 away from the base substrate 101, a light-emitting layer 7 disposed on a side of the pixel definition layer 6 away from the base substrate 101, and a cathode 3 disposed on a side of the light-emitting layer 7 away from the base substrate 101.

In an exemplary implementation, a connection via 30 is provided in the pixel definition layer 6, and the connection via 30 extends along a direction perpendicular to the base substrate 101. The connection via 30 penetrates the pixel definition layer 6, exposing at least a portion of the auxiliary cathode 20.

In an exemplary implementation, the light-emitting layer 7 is provided with a connection avoidance hole 70. The connection avoidance hole 70 is communication with the connection via 30, and an orthographic projection of the connection avoidance hole 70 on the base substrate covers the orthographic projection of the connection via 30 on the base substrate.

In an exemplary implementation, at least a portion of the cathode 3 fills the connection avoidance hole 70 and the connection via 30, covering sidewalls of the connection avoidance hole 70 and the connection via 30 and a bottom wall of the connection via 30. The cathode 3 is connected to the auxiliary cathode 20 through the connection avoidance hole 70 and the connection via 30.

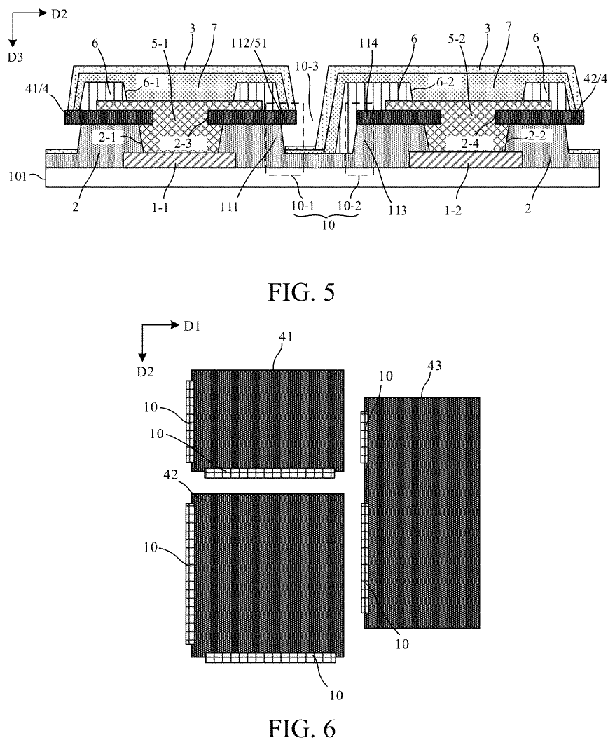

FIG. 5 is a schematic diagram of a cross-sectional structure of a display substrate according to an embodiment of the present disclosure, illustrating a cross-sectional view taken along a direction A-A′ in FIG. 4a. In an exemplary implementation, as shown in FIG. 5, in a direction perpendicular to the display substrate, the display substrate may include a base substrate 101, a first connection electrode 1-1 and a second connection electrode 1-2 provided on the base substrate 101, an organic dielectric layer 2 provided on a side of the first connection electrode 1-1 and the second connection electrode 1-2 away from the base substrate 101, an inorganic dielectric layer 4 provided on a side of the organic dielectric layer 2 away from the base substrate 101, a first anode 5-1 and a second anode 5-2 provided on a side of the inorganic dielectric layer 4 away from the base substrate 101, a pixel definition layer 6 provided on a side of the first anode 5-1 and the second anode 5-2 away from the base substrate 101, a light-emitting layer 7 disposed on a side of the pixel definition layer 6 away from the base substrate 101, and a cathode 3 disposed on a side of the light-emitting layer 7 away from the base substrate 101. Both the first anode 5-1 and the second anode 5-2 are electrically connected to the light-emitting layer 7, and the cathode 3 is electrically connected to the light-emitting layer 7, and the light-emitting layer 7 emits light when driven by the first anode 5-1 and the cathode 3, and/or emits light when driven by the second anode 5-2 and the cathode 3. The first anode 5-1, the light-emitting layer 7, and the cathode 3 form the light-emitting device of the first sub-pixel, the second anode 5-2, the light-emitting layer 7, and the cathode 3 form the light-emitting device of the second sub-pixel, and the light-emitting layer 7 and the cathode 3 may be a common layer connected together.

In an exemplary implementation, the first connection electrode 1-1 may be electrically connected to the pixel drive circuit of the first sub-pixel, and the second connection electrode 1-2 may be electrically connected to the pixel drive circuit of the second sub-pixel. The first connection electrode 1-1 and the second connection electrode 1-2 can be prepared by adopting the same kind of conductive thin film through the same preparation process, thereby simplifying the preparation process and reducing the production cost.

In an exemplary implementation, the organic dielectric layer 2 may be a common layer connected together. The organic dielectric layer 2 is provided with a first via 2-1 that exposes at least a portion of the first connection electrode 1-1 and a second via 2-2 that exposes at least a portion of the second connection electrode 1-2.

In an exemplary implementation, the inorganic dielectric layer 4 includes a first inorganic dielectric pattern 41 and a second inorganic dielectric pattern 42. The first inorganic dielectric pattern 41 and the second inorganic dielectric pattern 42 can be prepared by the same preparation process using the same inorganic thin film, thereby simplifying the preparation process and reducing the production cost.

In an exemplary implementation, a third via 2-3 is provided in the first inorganic dielectric pattern 41, and an orthographic projection of the third via 2-3 on the base substrate 101 is within an orthographic projection of the first via 2-1 on the base substrate 101. At least a portion of the sidewall of the third via 2-3 protrudes from the sidewall of the first via 2-1 in a direction parallel to the base substrate 101.

In an exemplary implementation, a fourth via 2-4 is provided in the second inorganic dielectric pattern 42, and an orthographic projection of the fourth via 2-4 on the base substrate 101 is within an orthographic projection of the second via 2-2 on the base substrate 101. At least a portion of the sidewall of the fourth via 2-4 protrudes from the sidewall of the second via 2-2 in a direction parallel to the base substrate 101.

In an exemplary implementation, the first anode 5-1 and the second anode 5-2 may be prepared by using the same conductive thin film and by the same preparation process, thereby simplifying the preparation process and reducing the production cost. The first anode 5-1 is connected to the first connection electrode 1-1 through the first via 2-1 and the third via 2-3, and the second anode 5-2 is connected to the second connection electrode 1-2 through the second via 2-2 and the fourth via 2-4.

In an exemplary implementation, the pixel definition layer 6 may be a common layer connected together. A first pixel opening 6-1 and a second pixel opening 6-2 are provided in the pixel definition layer 6, the first pixel opening 6-1 exposes at least a portion of the first anode 5-1, and at least a portion of the first anode 5-1 can serve as a bottom wall of the first pixel opening 6-1. The second pixel opening 6-2 exposes at least a portion of the second anode 5-2, and at least a portion of the second anode 5-2 may serve as a bottom wall of the second pixel opening 6-2.

In an exemplary implementation, the light-emitting layer 7 may be a common layer connected together. An orthographic projection of the light-emitting layer 7 on the base substrate 101 overlaps with orthographic projections of the first anode 5-1 and the second anode 5-2 on the base substrate 101. For example, the orthographic projection of the first anode 5-1 on the base substrate 101 is within the orthographic projection of the light-emitting layer 7 on the base substrate 101, and the orthographic projection of the second anode 5-2 on the base substrate 101 is within the orthographic projection of the light-emitting layer 7 on the base substrate 101. At least a portion of the light-emitting layer 7 covers the sidewall and the bottom wall of the first pixel opening 6-1, and at least a portion of the light-emitting layer 7 is electrically connected to the first anode 5-1 through the first pixel opening 6-1. At least a portion of the light-emitting layer 7 covers the sidewall and the bottom wall of the second pixel opening 6-2, and at least a portion of the light-emitting layer 7 is electrically connected to the second anode 5-2 through the second pixel opening 6-2.

In an exemplary implementation, the cathode 3 may be a common layer connected together. At least a portion of the cathode 3 is electrically connected to the light-emitting layer 7. An orthographic projection of at least a portion of the cathode 3 on the base substrate 101 overlaps with the orthographic projections of the first anode 5-1 and the second anode 5-2 on the base substrate 101. For example, the orthographic projection of the first anode 5-1 on the base substrate 101 is within the orthographic projection of the cathode 3 on the base substrate 101, and the orthographic projection of the second anode 5-2 on the base substrate 101 is within the orthographic projection of the cathode 3 on the base substrate 101.

In an exemplary implementation, in a direction perpendicular to the display substrate, the display substrate further includes a partition structure 10 disposed on the base substrate 101, and the partition structure 10 is located between adjacent sub-pixels to block light-emitting layers and cathodes of adjacent sub-pixels. For example, the partition structure 10 is located between the first sub-pixel and the second sub-pixel, and blocks the light-emitting layer and the cathode of the first sub-pixel from the light-emitting layer and the cathode of the second sub-pixel.

The base substrate according to an embodiment of the present disclosure blocks the light-emitting layer and the cathode of the adjacent sub-pixels through the partition structure 10 to avoid current crosstalk between the adjacent sub-pixels.

In an exemplary implementation, the partition structure 10 includes a first separation wall 10-1, a second separation wall 10-2, and a separation groove 10-3 positioned between the first separation wall 10-1 and the second separation wall 10-2. The first separation wall 10-1 is located on a side close to the first sub-pixel, and the second separation wall 10-2 is located on a side close to the second sub-pixel.

In an exemplary implementation, the first separation wall 10-1 includes a first separation layer 111 disposed on the base substrate 101 and a second separation layer 112 disposed on a side of the first separation layer 111 away from the base substrate 101. The first separation layer 111 can be integrally connected with the adjacent organic dielectric layer 2, and can be prepared by the same preparation process using the same organic thin film, thereby simplifying the preparation process and reducing the production cost. The second separation layer 112 can be integrally connected with the adjacent first inorganic dielectric pattern 41, and can be prepared by the same preparation process using the same inorganic thin film, thereby simplifying the preparation process and reducing the production cost.

In an exemplary implementation, at least a portion of the second separation layer 112 protrudes from a sidewall of the first separation layer 111 in a direction parallel to the base substrate 101 to form a boss 51. The pixel definition layer 6 covers a surface of the second separation layer 112 away from the base substrate, exposes at least a portion of the surface of the second separation layer 112 away from the base substrate and a side surface of the second separation layer 112, and the light-emitting layer 7 and the cathode 3 are blocked at the boss 51.

In an exemplary implementation, the second separation wall 10-2 includes a third separation layer 113 disposed on the base substrate 101 and a fourth separation layer 114 disposed on a side of the third separation layer 113 away from the base substrate 101. The third separation layer 113 can be integrally connected with the adjacent organic dielectric layer 2, and can be prepared by the same preparation process using the same organic thin film, thereby simplifying the preparation process and reducing the production cost. The fourth separation layer 114 can be integrally connected with the adjacent second inorganic dielectric pattern 42, and can be prepared by the same preparation process using the same organic thin film, thereby simplifying the preparation process and reducing the production cost.

In an exemplary implementation, a sidewall of the fourth separation layer 114 close to the first separation wall 10-1 and a sidewall of the third separation layer 113 close to the first separation wall 10-1 form a continuous flat surface. The stacked structure formed by the pixel definition layer 6, the light-emitting layer 7, and the cathode 3 covers the flat surface formed by the sidewall of the fourth separation layer 114 and the sidewall of the third separation layer 113.

In an exemplary implementation, a groove bottom of the separation groove 10-3 is the organic dielectric layer 2, and the stacked structure formed by the light-emitting layer 7 and the cathode 3 covers the groove bottom of the separation groove 10-3.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary implementation, the preparing process of the display substrate according to this embodiment may include the following operations.

(11) Forming an inorganic dielectric layer and a partition structure. In an exemplary implementation, forming the inorganic dielectric layer and the partition structure may include: first forming an organic dielectric layer on a base substrate; subsequently, depositing an inorganic insulating thin film on the organic dielectric layer, and patterning the inorganic insulating thin film by a patterning process to form an inorganic dielectric layer. The inorganic dielectric layer includes a first inorganic dielectric pattern 41, a second inorganic dielectric pattern 42, and a third inorganic dielectric pattern 43 disposed at intervals, and the first inorganic dielectric pattern 41, the second inorganic dielectric pattern 42, and the third inorganic dielectric pattern 43 all form a partition structure 10 with the organic dielectric layer, as shown in FIG. 6.

In an exemplary implementation, the shapes of the first inorganic dielectric pattern 41, the second inorganic dielectric pattern 42, and the third inorganic dielectric pattern 43 all include a rectangle. The first inorganic dielectric pattern 41 and the second inorganic dielectric pattern 42 are disposed at intervals along the second direction D2 to form an inorganic dielectric pattern row, and the third inorganic dielectric pattern 43 is located on a side of the inorganic dielectric pattern row in the first direction D1.

In an exemplary implementation, the shape of the partition structure 10 includes a linear shape, and the partition structure 10 may be located on at least one side of the first inorganic dielectric pattern 41, the second inorganic dielectric pattern 42, and the third inorganic dielectric pattern 43. For example, the partition structure 10 may be located on a side of the first inorganic dielectric pattern 41 in the second direction D2, and/or, the partition structure 10 may be located on a side of the first inorganic dielectric pattern 41 in a direction opposite to the first direction D1, and/or, the partition structure 10 may be located on a side of the second inorganic dielectric pattern 42 in the second direction D2, and/or, the partition structure 10 may be located on a side of the second inorganic dielectric pattern 42 in the direction opposite to the first direction D1, and/or, the partition structure 10 may be located on a side of the third inorganic dielectric pattern 43 in the direction opposite to the first direction D1, and located between the third inorganic dielectric pattern 43 and the first inorganic dielectric pattern 41, and/or, the partition structure 10 may be located on a side of the third inorganic dielectric pattern 43 in the direction opposite to the first direction D1, and located between the third inorganic dielectric pattern 43 and the second inorganic dielectric pattern 42.

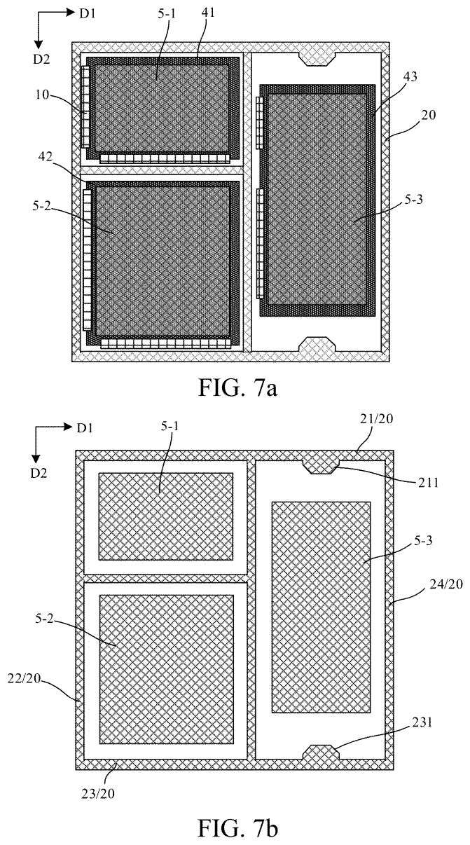

(12) Forming a first anode, a second anode, a third anode, and an auxiliary cathode. In an exemplary implementation, forming the first anode, the second anode, the third anode, and the auxiliary cathode may include: depositing a first conductive thin film on the base substrate on which the aforementioned pattern is formed, patterning the first conductive thin film by a patterning process to form a first anode 5-1, a second anode 5-2, a third anode 5-3, and an auxiliary cathode 20. The auxiliary cathode 20 is spaced apart from the first anode 5-1, the second anode 5-2, and the third anode 5-3, as shown in FIGS. 7a and 7b.

In an exemplary implementation, the shapes of the first anode 5-1, the second anode 5-2, and the third anode 5-3 each include a rectangular shape. The first anode 5-1 and the second anode 5-2 are disposed at intervals along the second direction D2 to form an anode column, and the third anode 5-3 is located on a side of the anode column in the first direction D1.

In an exemplary implementation, an orthographic projection of the first anode 5-1 on the base substrate is within an orthographic projection of the first inorganic dielectric pattern 41 on the base substrate. An orthographic projection of the second anode 5-2 on the base substrate is within an orthographic projection of the second inorganic dielectric pattern 42 on the base substrate. An orthographic projection of the third anode 5-3 on the base substrate is within an orthographic projection of the third inorganic dielectric pattern 43 on the base substrate.

In an exemplary implementation, the shape of the auxiliary cathode 20 is grid-like. The auxiliary cathode 20 may be disposed around the periphery of the first sub-pixel region 100, around the periphery of the second sub-pixel region 200, and around the periphery of the third sub-pixel region 300.

In an exemplary implementation, the auxiliary cathode 20 includes a first side portion 21, a second side portion 22, a third side portion 23, a fourth side portion 24, a fifth side portion 25, and a sixth side portion 26. The shape of the first side portion 21 is a linear shape and extends along the first direction D1, and the first side portion 21 is located on a side of the first sub-pixel region 100 and the third sub-pixel region 300 in a direction opposite to the second direction D2. A first end of the first side portion 21 is connected to a first end of the second side portion 22, and a second end of the first side portion 21 is connected to a first end of the fourth side portion 24. The shape of the second side portion 22 is a linear shape and extends along the second direction D2, and the second side portion 22 is located on a side of the first sub-pixel region 100 and the second sub-pixel region 200 in a direction opposite to the first direction D1. The first end of the second side portion 22 is connected to the first end of the first side portion 21, and a second end of the second side portion 22 is connected to a first end of the third side portion 23. The shape of the third side portion 23 is a linear shape and extends along the first direction D1, and the third side portion 23 is located on a side of the second sub-pixel region 200 and the third sub-pixel region 300 in the second direction D2. A first end of the third side portion 23 is connected to the second end of the second side portion 22, and a second end of the third side portion 23 is connected to a second end of the fourth side portion 24. The shape of the fourth side portion 24 is a linear shape and extends along the second direction D2, and the fourth side portion 24 is located on a side of the third sub-pixel region 300 in the first direction D1. The first end of the fourth side portion 24 is connected to the second end of the first side portion 21, and the second end of the fourth side portion 24 is connected to the second end of the third side portion 23. The shape of the fifth side portion 25 is a linear shape and extends along the first direction D1, and the fifth side portion 25 is located between the first sub-pixel region 100 and the second sub-pixel region 200. A first end of the fifth side portion 25 is connected to a middle portion of the second side portion 22, and a second end of the fifth side portion 25 is connected to a middle portion of the sixth side portion 26. The shape of the sixth side portion 26 is a linear shape and extends along the second direction D2, and the sixth side portion 26 is located between the first sub-pixel region 100 and the third sub-pixel region 300 and between the second sub-pixel region 200 and the third sub-pixel region 300. A first end of the sixth side portion 26 is connected to a middle portion of the first side portion 21, and a second end of the sixth side portion 26 is connected to a middle portion of the third side portion 23.

In an exemplary implementation, the first side portion 21 of the auxiliary cathode 20 is provided with a first bump 211 that protrudes from the edge of the first side portion 21 in the second direction D2, and the first bump 211 protrudes in a direction toward the third anode 5-3. The third side portion 23 of the auxiliary cathode 20 is provided with a second bump 231 protruding from the edge of the third side portion 23 in the second direction D2, and the second bump 231 protrudes in a direction toward the third anode 5-3.

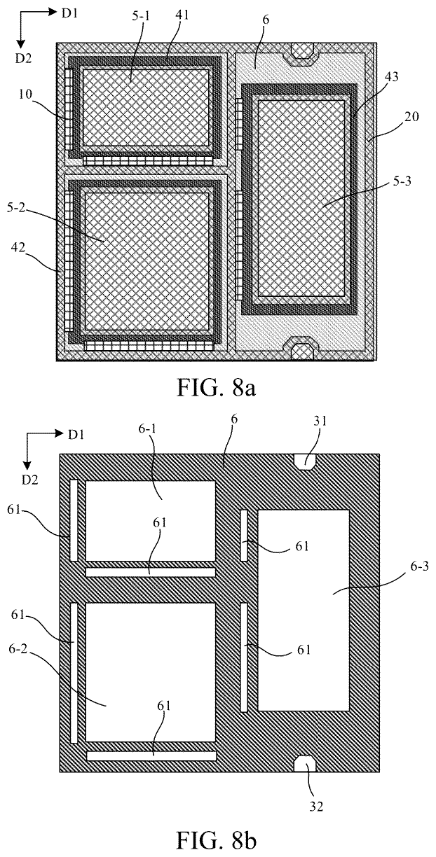

(13) Forming a pixel definition layer. In an exemplary implementation, forming the pixel definition layer may include: depositing a pixel definition thin film covering the first anode 5-1, the second anode 5-2, the third anode 5-3, and the auxiliary cathode 20 on the base substrate on which the aforementioned pattern is formed, and patterning the pixel definition thin film by a patterning process to form the pixel definition layer 6, as shown in FIGS. 8a and 8b.

In an exemplary implementation, a first pixel opening 6-1, a second pixel opening 6-2, and a third pixel opening 6-3 are provided in the pixel definition layer 6, and the first pixel opening 6-1 exposes at least a portion of the first anode 5-1 which may serve as a bottom wall of the first pixel opening 6-1. The second pixel opening 6-2 exposes at least a portion of the second anode 5-2, which may serve as a bottom wall of the second pixel opening 6-2; and the third pixel opening 6-3 exposes at least a portion of the third anode 5-3, which may serve as a bottom wall of the third pixel opening 6-3.

In an exemplary implementation, a first connection via 31 and a second connection via 32 are provided in the pixel definition layer 6, and the first connection via 31 is located on a side of the third pixel opening 6-3 in a direction opposite to the second direction D2, exposing the first bump of the auxiliary cathode 20. The second connection via 32 is located on a side of the third pixel opening 6-3 in the second direction D2, exposing the second bump of the auxiliary cathode 20.

In an exemplary implementation, at least one first partition avoidance hole 61 is provided in the pixel definition layer 6, the first partition avoidance hole 61 is provided corresponding to the partition structure 10, and an orthographic projection of the first partition avoidance hole 61 on the base substrate overlaps with an orthographic projection of the partition structure 10 on the base substrate. The first partition avoidance hole 61 exposes at least a portion of the partition structure 10, so that the light-emitting layer and the cathode formed later can contact the partition structure 10 at the first partition avoidance hole 61 and be blocked at the partition structure 10.

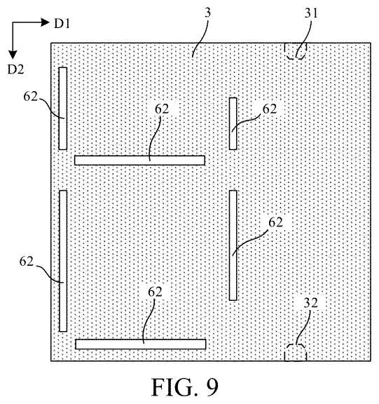

(14) Forming a light-emitting layer and a cathode. In an exemplary implementation, forming the light-emitting layer and the cathode may include: first depositing a light-emitting layer covering the pixel definition layer 6 on the base substrate on which the aforementioned pattern is formed, wherein the light-emitting layer may be a common layer connected together, the light-emitting layer is connected to the first anode 5-1 through the first pixel opening 6-1, the light-emitting layer is connected to the second anode 5-2 through the second pixel opening 6-2, and the light-emitting layer is connected to the third anode 5-3 through the third pixel opening 6-3; and the light-emitting layer is blocked at the partition structure 10; the light-emitting layer is provided with a first connection avoidance hole and a second connection avoidance hole, an orthographic projection of the first connection avoidance hole on the base substrate overlaps with the orthographic projection of the first bump 211 of the auxiliary cathode 20 on the base substrate, and an orthographic projection of the second connection avoidance hole on the base substrate overlaps with the orthographic projection of the second bump 231 of the auxiliary cathode 20 on the base substrate; subsequently, depositing a second conductive thin film on the light-emitting layer, and patterning the second conductive thin film by a patterning process to form a cathode 3, as shown in FIGS. 9 and 4a.

In an exemplary implementation, the cathode 3 may be a common layer connected together, the cathode 3 is connected to the light-emitting layer, and the cathode 3 is blocked at the partition structure 10.

In an exemplary implementation, the orthographic projection of the cathode 3 on the base substrate overlaps with the orthographic projections of the first anode 5-1, the second anode 5-2, the third anode 5-3 and the auxiliary cathode 20 on the base substrate. For example, the orthographic projection of the first anode 5-1 on the base substrate is within the orthographic projection of the cathode 3 on the base substrate, the orthographic projection of the second anode 5-2 on the base substrate is within the orthographic projection of the cathode 3 on the base substrate, the orthographic projection of the third anode 5-3 on the base substrate is within the orthographic projection of the cathode 3 on the base substrate, and the orthographic projection of the auxiliary cathode 20 on the base substrate is within the orthographic projection of the cathode 3 on the base substrate.

In an exemplary implementation, the cathode 3 may be connected to the first bump of the auxiliary cathode 20 through the first connection via 31, and the cathode 3 may be connected to the second bump of the auxiliary cathode 20 through the second connection via 32, so that the face resistance of the cathode 3 may be reduced through the auxiliary cathode 20.

In an exemplary implementation, at least one second partition avoidance hole 62 is provided in the cathode 3, the second partition avoidance hole 62 is provided corresponding to the partition structure 10, and the cathode 3 is blocked at the partition structure 10 to form the second partition avoidance hole 62.

An embodiment of the present disclosure further provides a method for preparing a display substrate, including: forming a partition structure on a base substrate; forming a conductive thin film on the base substrate, such that the conductive thin film forms an anode and an auxiliary cathode that are insulated from each other, wherein an orthographic projection of the anode on the base substrate does not overlap with an orthographic projection of the partition structure on the base substrate, and an orthographic projection of the auxiliary cathode on the base substrate does not overlap with the orthographic projection of the partition structure on the base substrate; forming a light-emitting layer on a side of the anode away from the base substrate, the light-emitting layer being connected to the anode, and the light-emitting layer being blocked at the partition structure; and forming a cathode on a side of the light-emitting layer away from the base substrate, the cathode being connected to the light-emitting layer, the cathode being blocked at the partition structure, and the cathode being electrically connected to the auxiliary cathode.

An embodiment of the present disclosure further provides a display apparatus, including a display substrate described above. The display apparatus may be any product or component with a display function, such as a mobile phone, a tablet computer, a television, a display, a laptop computer, a digital photo frame, and a navigator, which is not limited in the embodiments of the present invention.

Those of ordinary skills in the art may understand that all or some of acts in the methods disclosed above, systems, functional modules or units in apparatuses may be implemented as software, firmware, hardware, and an appropriate combination thereof. In a hardware implementation mode, division of the function modules/units mentioned in the above description is not always corresponding to division of physical components. For example, a physical component may have multiple functions, or a function or an act may be executed by several physical components in cooperation. Some components or all components may be implemented as software executed by a processor such as a digital signal processor or a microprocessor, or implemented as hardware, or implemented as an integrated circuit such as an application specific integrated circuit. Such software may be distributed on a computer readable medium, and the computer readable medium may include a computer storage medium (or a non-transitory medium) and a communication medium (or a transitory medium). As known to those of ordinary skills in the art, a term computer storage medium includes volatile and nonvolatile, and removable and irremovable media implemented in any method or technology for storing information (for example, a computer readable instruction, a data structure, a program module, or other data). The computer storage medium includes, but is not limited to, a Random Access Memory (RAM), a Read-Only Memory (ROM), an Electrically Erasable Programmable ROM (EEPROM), a flash memory or other memory technologies, a Compact Disc Read-Only Memory (CD-ROM), a Digital Video Disk (DVD) or other optical discs, a cassette, a magnetic tape, a disk memory or other magnetic storage apparatus, or any other medium configurable to store expected information and accessible by a computer. In addition, it is known to those of ordinary skill in the art that the communication medium usually includes a computer readable instruction, a data structure, a program module, or other data in a modulated data signal of a carrier wave or another transmission mechanism and the like, and may include any information delivery medium.

1. A display substrate, comprising:
a partition structure disposed on a base substrate;
an anode disposed on the base substrate, an orthographic projection of the anode on the base substrate not overlapping with an orthographic projection of the partition structure on the base substrate;
a light-emitting layer disposed on a side of the anode away from the base substrate, the light-emitting layer being connected to the anode and blocked at the partition structure;
a cathode disposed on a side of the light-emitting layer away from the base substrate, the cathode being connected to the light-emitting layer and blocked at the partition structure; and
an auxiliary cathode located in the same film layer as the anode, the auxiliary cathode and the anode being insulated from each other, and the auxiliary cathode being electrically connected to the cathode.

2. The display substrate according to claim 1, further comprising a connection via disposed between the auxiliary cathode and the cathode, wherein the cathode is connected to the auxiliary cathode through the connection via, and an orthographic projection of the connection via on the base substrate does not overlap with either the orthographic projection of the anode on the base substrate or the orthographic projection of the partition structure on the base substrate.

3. The display substrate according to claim 2, wherein a connection avoidance hole is provided in the light-emitting layer, and an orthographic projection of the connection avoidance hole on the base substrate covers the orthographic projection of the connection via on the base substrate.

4. The display substrate according to claim 1, wherein the auxiliary cathode and the anode comprise a same conductive material.

5. The display substrate according to claim 1, wherein a shape of the auxiliary cathode is grid-like.

6. The display substrate according to claim 1, wherein a bump is provided on the auxiliary cathode, the bump protrudes from an edge of the auxiliary cathode, and the bump is electrically connected to the cathode.

7. The display substrate according to claim 1, wherein an orthographic projection of the auxiliary cathode on the base substrate is within an orthographic projection of the cathode on the base substrate.

8. The display substrate according to claim 1, wherein the partition structure comprises a first separation wall disposed on the base substrate, the first separation wall comprises a first separation layer and a second separation layer disposed on a side of the first separation layer away from the base substrate, at least a portion of the second separation layer protrudes from a sidewall of the first separation layer along a direction parallel to the base substrate to form a boss at which the light-emitting layer and the cathode are blocked.

9. The display substrate according to claim 8, wherein the partition structure further comprises a second separation wall, a separation groove is formed between the second separation wall and the first separation wall, the second separation wall comprises a third separation layer and a fourth separation layer disposed on a side of the third separation layer away from the base substrate, at least a portion of a stacked structure formed by the light-emitting layer and the cathode covers a sidewall of the third separation layer and a sidewall of the fourth separation layer, and at least a portion of the stacked structure formed by the light-emitting layer and the cathode covers a groove bottom of the separation groove.

10. The display substrate according to claim 9, further comprising an organic dielectric layer and an inorganic dielectric layer, wherein the organic dielectric layer is disposed on the base substrate, the inorganic dielectric layer is disposed on a side of the organic dielectric layer away from the base substrate, the anode is disposed on a side of the inorganic dielectric layer away from the base substrate, the first separation layer is integrally connected with the organic dielectric layer adjacent thereto, the third separation layer is integrally connected with the organic dielectric layer adjacent thereto, the second separation layer is integrally connected with the inorganic dielectric layer adjacent thereto, the fourth separation layer is integrally connected with the inorganic dielectric layer adjacent thereto, and the groove bottom of the separation groove is the organic dielectric layer.

11. The display substrate according to claim 1, comprising a first sub-pixel region, a second sub-pixel region and a third sub-pixel region, wherein the first sub-pixel region comprises a first anode, a light-emitting layer, and a cathode, the second sub-pixel region comprises a second anode, a light-emitting layer, and a cathode, the third sub-pixel region comprises a third anode, a light-emitting layer, and a cathode, the first sub-pixel region and the second sub-pixel region are arranged along a second direction to form a sub-pixel column, the third sub-pixel region is located on a side of the sub-pixel column in a first direction, the partition structure is provided on at least one side of the first sub-pixel region, the second sub-pixel region, the third sub-pixel region, and the first direction intersects with the second direction.

12. The display substrate according to claim 11, wherein the auxiliary cathode is disposed around a periphery of the first sub-pixel region, around a periphery of the second sub-pixel region, and around a periphery of the third sub-pixel region.

13. The display substrate according to claim 11, further comprising a connection via disposed between the auxiliary cathode and the cathode, wherein the cathode is connected to the auxiliary cathode through the connection via, an orthographic projection of the connection via on the base substrate does not overlap with either the orthographic projection of the anode on the base substrate or the orthographic projection of the partition structure on the base substrate, and the connection via is located on at least one side of the third sub-pixel region in the second direction.

14. The display substrate according to claim 11, comprising a first partition structure, a second partition structure, a third partition structure, a fourth partition structure, a fifth partition structure, and a sixth partition structure; wherein a shape of the first partition structure comprises a linear shape extending along the first direction, and the first partition structure is disposed between the first sub-pixel region and the second sub-pixel region; a shape of the second partition structure comprises a linear shape extending along the second direction, and the second partition structure is disposed on a side of the first sub-pixel region away from the third sub-pixel region; a shape of the third partition structure comprises a linear shape extending along the first direction, and the third partition structure is disposed on a side of the second sub-pixel region away from the first sub-pixel region; a shape of the fourth partition structure comprises a linear shape extending along the second direction, and the fourth partition structure is disposed on a side of the second sub-pixel region away from the third sub-pixel region; a shape of the fifth partition structure comprises a linear shape extending along the second direction, and the fifth partition structure is disposed between the third sub-pixel region and the first sub-pixel region; and a shape of the sixth partition structure comprises a linear shape extending along the second direction, and the sixth partition structure is disposed between the third sub-pixel region and the second sub-pixel region.

15. The display substrate according to claim 1, further comprising a pixel definition layer disposed on the side of the anode away from the base substrate, wherein the pixel definition layer is provided with a pixel opening that exposes at least a portion of the anode, the light-emitting layer covers the pixel opening and is connected with the anode, the pixel definition layer is further provided with a connection via through which the cathode is connected with the auxiliary cathode, and an orthographic projection of the connection via on the base substrate does not overlap with either the orthographic projection of the anode on the base substrate or the orthographic projection of the partition structure on the base substrate.

16. The display substrate according to claim 15, wherein the pixel definition layer is further provided with a partition avoidance hole, and an orthographic projection of the partition avoidance hole on the base substrate overlaps with the orthographic projection of the partition structure on the base substrate.

17. A display apparatus, comprising the display substrate according to claim 1.

18. A method for preparing a display substrate, comprising:
forming a partition structure on a base substrate;
forming a conductive thin film on the base substrate, such that the conductive thin film forms an anode and an auxiliary cathode that are insulated from each other, wherein an orthographic projection of the anode on the base substrate does not overlap with an orthographic projection of the partition structure on the base substrate, and an orthographic projection of the auxiliary cathode on the base substrate does not overlap with the orthographic projection of the partition structure on the base substrate;
forming a light-emitting layer on a side of the anode away from the base substrate, the light-emitting layer being connected to the anode, and the light-emitting layer being blocked at the partition structure; and
forming a cathode on a side of the light-emitting layer away from the base substrate, the cathode being connected to the light-emitting layer, the cathode being blocked at the partition structure, and the cathode being electrically connected to the auxiliary cathode.

19. The display substrate according to claim 2, wherein the partition structure comprises a first separation wall disposed on the base substrate, the first separation wall comprises a first separation layer and a second separation layer disposed on a side of the first separation layer away from the base substrate, at least a portion of the second separation layer protrudes from a sidewall of the first separation layer along a direction parallel to the base substrate to form a boss at which the light-emitting layer and the cathode are blocked.

20. The display substrate according to claim 2, comprising a first sub-pixel region, a second sub-pixel region and a third sub-pixel region, wherein the first sub-pixel region comprises a first anode, a light-emitting layer, and a cathode, the second sub-pixel region comprises a second anode, a light-emitting layer, and a cathode, the third sub-pixel region comprises a third anode, a light-emitting layer, and a cathode, the first sub-pixel region and the second sub-pixel region are arranged along a second direction to form a sub-pixel column, the third sub-pixel region is located on a side of the sub-pixel column in a first direction, the partition structure is provided on at least one side of the first sub-pixel region, the second sub-pixel region, the third sub-pixel region, and the first direction intersects with the second direction.
